(19) United States
(12) Patent Application Publication
(10) Pub. No.: US 2006/0254752 A1
(43) Pub. Date: Nov. 16, 2006

(54) Radiator and heatsink apparatus having the radiator

(75) Inventors: Shigeru Narakino, Fukuoka (JP); Wataru Utsunomiya, Fukuoka (JP); Youichi Hatanaka, Fukuoka (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd., Osaka (JP)

(21) Appl. No.: 11/396,510

(22) Filed: Apr. 4, 2006

(30) Foreign Application Priority Data
Apr. 6, 2005 (JP) P2005-109673

(51) Int. Cl. H05K 7/20

(52) U.S. Cl. 165/80.4; 165/125; 361/699

(57) ABSTRACT

A radiator includes: an inlet header having a hollow shape and being provided with an inlet for the coolant to enter; a plurality of flat tubes connecting to the inlet header on one end; and an outlet header having a hollow shape and being provided with an outlet for the coolant to discharge, the outlet header connecting to another end of the plurality of flat tubes. The plurality of flat tubes form channels for the coolant and connect the inlet header and the outlet header.

### BACKGROUND OF THE INVENTION

1. Field of the Invention

The present invention relates to a radiator, which is employed in a liquid cooling system or the like that uses a pump to forcibly circulate a coolant, and a heatsink apparatus having the radiator.

2. Description of Related Art

Recent computers have shown extremely rapid improvement in data processing speed and thus CPUs operate at clock frequencies significantly higher than in the past.

Heat generated from the CPUs has increased accordingly. Therefore, in addition to a conventional heat dissipation method, in which a heat-dissipating portion, such as a heatsink or heat-dissipating fins, contacts a heat-generating portion, it is indispensable to employ other cooling methods, including: directly cooling the heatsink using a fan; air cooling a heat-dissipating portion in a heatsink module, in which a heat pipe thermally connects a heat-receiving portion to the heat-dissipating portion, using a fan; and liquid cooling where a pump forcibly circulates a liquid coolant having high thermal conductivity, so as to transfer heat from a heat-receiving portion to a heat-dissipating portion for heat exchange in each portion.

Meanwhile, electronic devices are desired to be more compact, thus requiring further improvement in cooling performance and cooling efficiency.

As a conventional technology, a heatsink apparatus is disclosed in Related Art 1, for example.

FIG. 15 shows an overall structure of the heatsink apparatus, wherein coolant tank 101 and heat-dissipating tubes 102 are formed of extruded material and disposed in substantially parallel in a same direction.

Heat-dissipating tubes 102 along with heat-dissipating fins 103 form a condensed portion, wherein heat-dissipating tubes 102 and heat-dissipating fins 103 are alternately disposed in a plurality of rows.

Headers 104 include header 104A, to which one end openings of coolant tank 101 and heat-dissipating tubes 102 are attached; and header 104B, to which the other end openings of coolant tank 101 and heat-dissipating tubes 102 are attached.

Each of headers 104 is formed of two sheets of plate members 104a and 104b, which are press-molded to have a substantially rectangular shape. Only peripheries of plate members 104a and 104b are bonded so as to form a flat hollow shape. Plate member 104b has openings, to which the end openings of coolant tank 101 and heat-dissipating tubes 102 are inserted.

Thus, heat-dissipating tubes 102 and plate members 104a and 104b can be formed thin, thereby providing a large heat-dissipating surface area.

Although not shown in the figure, another conventional technology is disclosed in Related Art 2, wherein a bag-shaped flexible sheet having high heat resistance and good thermal conductivity is used as a radiator of a coolant. The coolant evenly flows inside the entire flexible sheet, which evens out a temperature across a heat-dissipating surface and thereby improves heat dissipation performance.

Having flexibility, the radiator is easily installed in a narrow space in an electronic device and is further adaptable to a thinner electronic device.

[Related Art 1] Japanese Patent Laid-open Publication Hei 10-335552 (FIG. 2 on page 6)

[Related Art 1] Japanese Patent Laid-open Publication 2001-237582 (FIG. 1 on page 11)

The above-described heat-dissipating tubes of the heatsink apparatus disclosed in Related Art 1 have a large surface area for heat dissipation and is capable of further increasing heat dissipation performance when a fan is used together. However, since the heat-dissipating tubes, which provide channels for the coolant, are processed by extrusion, the channels can only have a straight line shape. When a space for heat dissipation inside an electronic device is complicated, for example, it is difficult to efficiently fit the heatsink apparatus into the space.

Further, the heat-dissipating tubes cannot have a concave-convex shape on its internal wall, thus hampering improvement in heat dissipation efficiency by using turbulence of the coolant.

In the radiator disclosed in Related Art 2, which bonds opposing flexible sheets made of thermoplastic resin material to form a bag shape, a channel of the coolant distends due to internal pressure. Further, since the flexible sheets per se have no definite shape, it is difficult to ensure an air channel when, for example, a plurality of flexible sheets are arranged in layers so as to blow air through gaps formed therebetween. It is therefore not suitable for improving the heat dissipation performance.

### SUMMARY OF THE INVENTION

The present invention is provided to overcome the above-identified conventional problems. A purpose of the present invention is to improve cooling performance, to reduce a size of a heatsink apparatus and to effectively use a space for heat dissipation.

The present invention relates to a radiator circulating a coolant therein and dissipating heat of the coolant. The radiator includes: an inlet header having a hollow shape and being provided with an inlet for the coolant to enter; a plurality of flat tubes connecting to the inlet header on one end; and an outlet header having a hollow shape and being provided with an outlet for the coolant to discharge, the outlet header connecting to another end of the flat tubes. The flat tubes form channels for the coolant and connect the inlet header and the outlet header.

### BRIEF DESCRIPTION OF THE DRAWINGS

The present invention is further described in the detailed description which follows, with reference to the noted plurality of drawings by way of non-limiting examples of exemplary embodiments of the present invention, in which like reference numerals represent similar parts throughout the several views of the drawings, and wherein:

FIG. 1 is a perspective view of a radiator according to a first embodiment of the present invention;

FIG. 2 is a perspective cross-sectional view of the radiator according to the first embodiment;

FIG. 3 is an exploded view of a flat tube of the radiator according to the first embodiment;

FIG. 4 is an exploded view of a flat tube having a different shape according to the first embodiment;

FIG. 5 (a), (b) are perspective views of a complete heat-dissipating part installed with the radiator according to the first embodiment;

FIG. 6 (a) is a plain view of the uncovered complete heat-dissipating part installed with the radiator according to the first embodiment; FIG. 6 (b) is a cross-sectional view along line AA of FIG. 6 (a);

FIG. 7 is a perspective view of a radiator according to a second embodiment of the present invention;

FIG. 8 is a plain view of an uncovered complete heat-dissipating part installed with a radiator according to a third embodiment of the present invention;

FIG. 9 is a plain view of an uncovered complete heat-dissipating part installed with a radiator according to a forth embodiment of the present invention;

FIG. 10 is a plain view of an uncovered complete heat-dissipating part installed with a radiator according to a fifth embodiment of the present invention;

FIG. 11 is a perspective view of a radiator according to a sixth embodiment of the present invention;

FIG. 12 is a perspective view of a radiator according to a seventh embodiment of the present invention;

FIG. 13 is a perspective view of a radiator according to an eighth embodiment of the present invention;

FIG. 14 (a) is a plain view of a radiator according to a ninth embodiment of the present invention; FIG. 14 (b) is a cross-sectional view along line BB of FIG. 14 (a);

FIG. 15 illustrates an overall structure of a conventional heatsink apparatus; and

FIG. 16 illustrates a heatsink apparatus installed with the complete heat-dissipating part according to the embodiment.

### DETAILED DESCRIPTION OF PREFERRED EMBODIMENTS

The embodiments of the present invention are explained in the following, with reference to the above-described drawings.

### First Embodiment

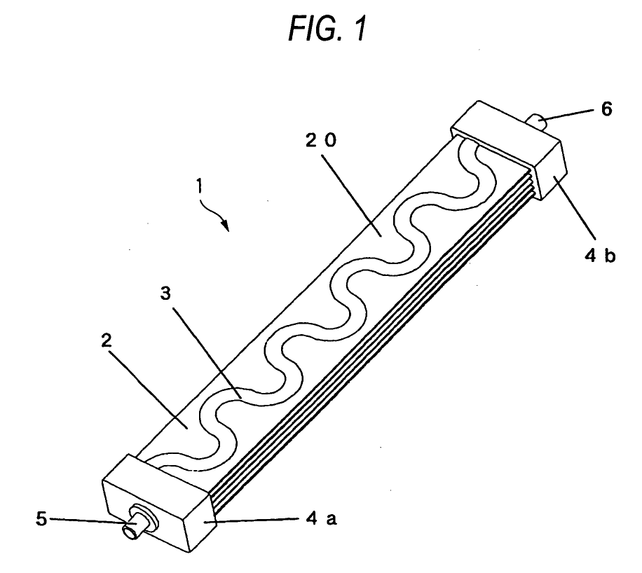

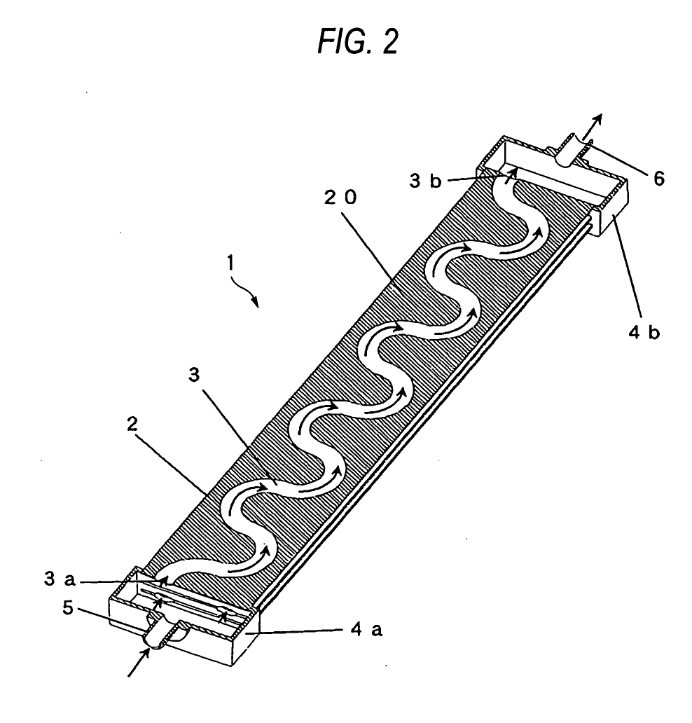

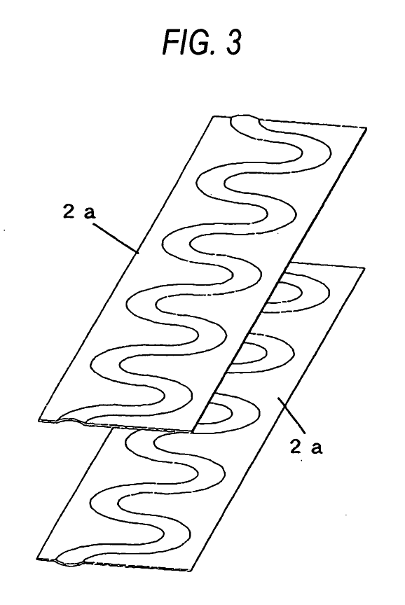

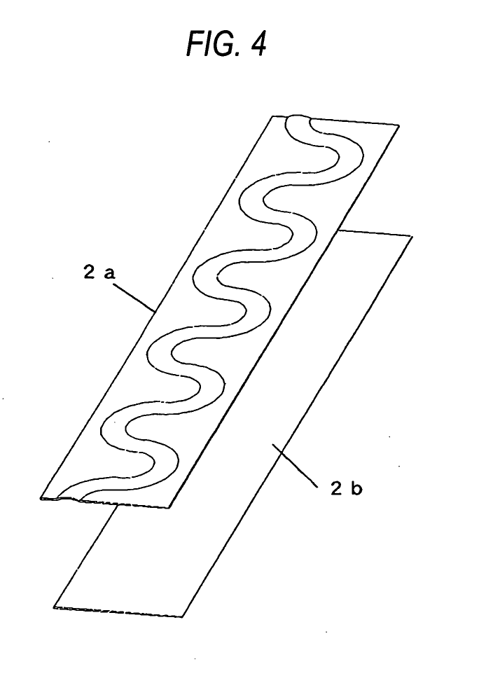

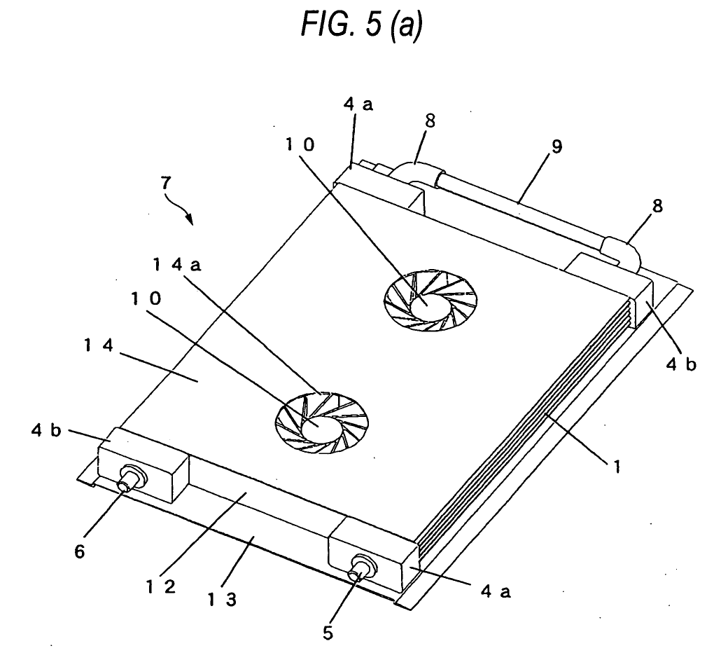

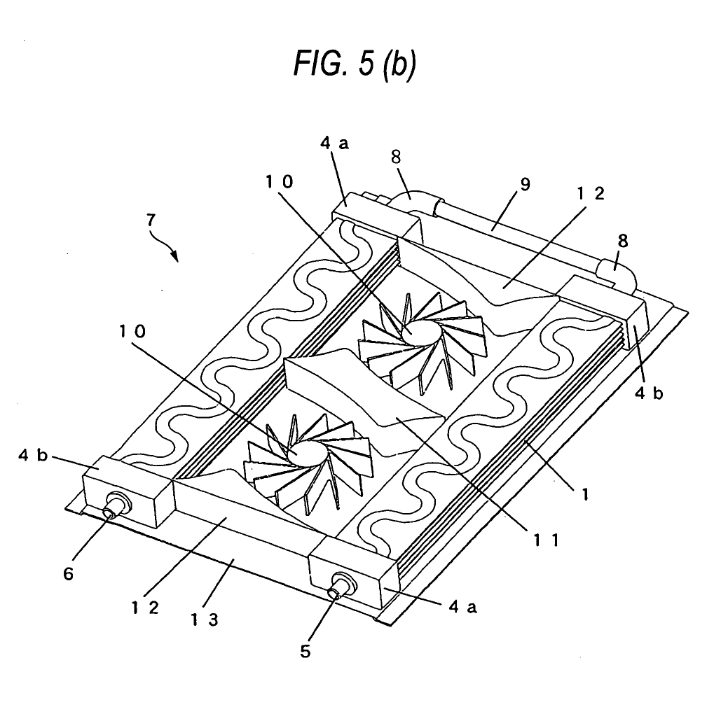

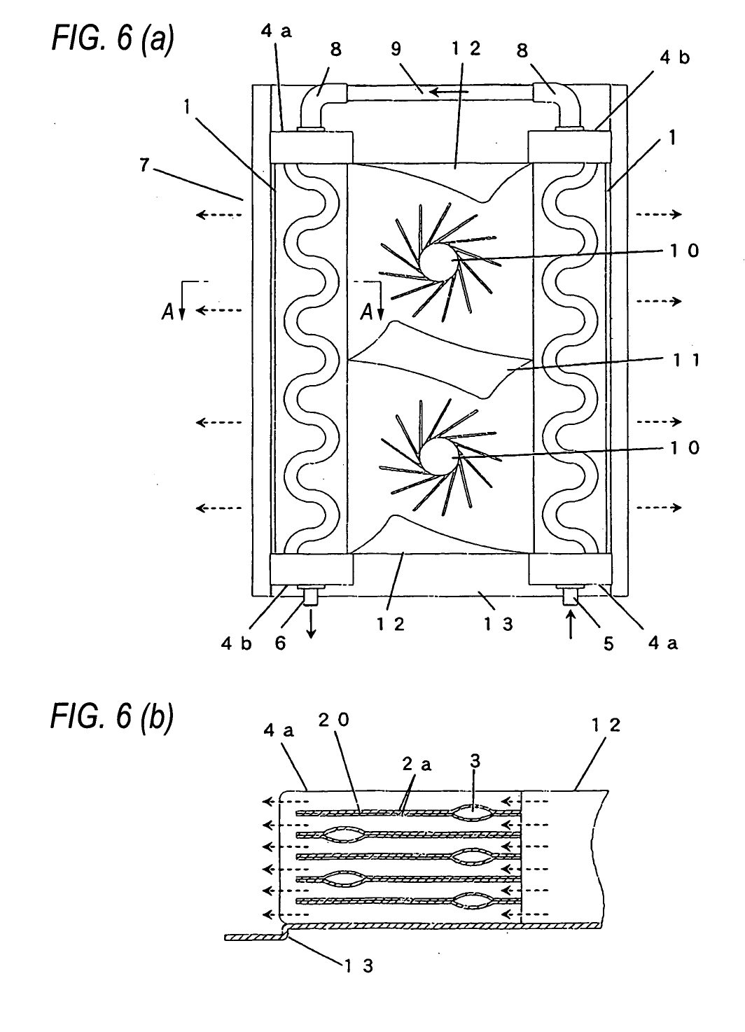

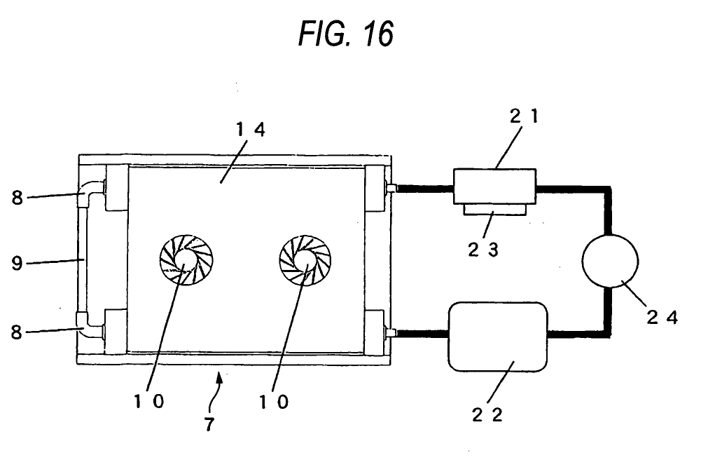

FIG. 1 is a perspective view of a radiator according to a first embodiment of the present invention. FIG. 2 is a perspective cross-sectional view of the radiator according to the embodiment. FIG. 3 is an exploded view of a flat tube of the radiator according to the embodiment. FIG. 4 is an exploded view of a flat tube having a different shape according to the embodiment. FIG. 5 (a), (b) are perspective views of a complete heat-dissipating part installed with the radiator according to the embodiment. FIG. 6 (a) is a plain view of the uncovered complete heat-dissipating part installed with the radiator according to the embodiment. FIG. 6 (b) is a cross-sectional view along line AA of FIG. 6 (a). FIG. 16 illustrates a heatsink apparatus installed with the complete heat-dissipating part according to the embodiment.

As shown in FIG. 1, flat tube 2 is formed by bonding two flat metal plates having good thermal conductivity and a definite shape. On a flat metal plate, channel 3 is press-formed in advance for coolant circulation and planar portion 20 is provided for heat dissipation. A plurality of flat tubes 2 are stacked in layers having a predetermined distance therebetween.

To both ends of the plurality of flat tubes 2 stacked in layers, hollow inlet header 4a and outlet header 4b are connected respectively. Inlet header 4a is provided with inlet 5 for the coolant to enter and outlet header 4b with outlet 6 for the coolant to discharge.

Further, inlet 5 and channels 3 are connected via a hollow portion of inlet header 4a. Outlet 6 and channels 3 are connected via a hollow portion of outlet header 4b.

As shown in FIG. 2, the coolant sent by a circulation pump (not shown in the figure) enters from inlet 5 in a direction of an arrow, passes through inlet header 4a, then enters channels 3 from inlets 3a of channels 3 located at an end of respective flat tubes 2. The coolant forced through channels 3 discharges from outlets 3b of channels 3 to a hollow portion of outlet header 4b, then discharges from outlet 6.

Serpentine-shaped channel 3 of the flat tube has a long distance, which allows a long heat dissipation time of the coolant as circulating in channel 3 and thereby further improves heat dissipation efficiency.

Further, planar portion 20 serves as a heat-dissipating fin, thus requiring no material as the heat-dissipating fin and allowing easy cost reduction.

Furthermore, channel 3 and planar portion 20 serving as the heat-dissipating fin are formed of an integrated material and require no thermal connection, thereby resulting in no loss in thermal conductivity at a thermally connected portion and allowing efficient heat transfer to planar portion 20. In addition, no manufacturing failure in thermal connection provides a highly reliable radiator.

As shown in FIG. 3, when channel 3 has a plane symmetrical shape with respect to a bonded surface of flat plate 2a, two flat plates having a channel of the same shape on one side may be bonded to form the flat tube, which allows easy assembly in manufacturing and easy reduction in size and cost. It is further possible to form flat tubes 2 of a same metal.

When channel 3 does not have a plane symmetrical shape with respect to a bonded surface of flat plate 2a, flat plate 2a having channel 3 on one side and flat plate 2b having no channel may be bonded as shown in FIG. 4. Press-molding both flat plates 2a and 2b makes it easy to form a channel having a complicated shape.

When forming flat tubes 2, it is preferable to bond flat plates 2a having good thermal conductivity, such as copper and aluminum, on which coolant channels 3 are formed in advance, using a brazing filler material having a plate or string (bar) shape or of a paste type. However, other bonding methods may be employed. For instance, flat plates 2a, which sandwich a clad material applied with a brazing filler material, may be placed in a high temperature oven filled with an inert gas such as nitrogen and argon for bonding. Flat plates 2a may also be glued using an adhesive suitable for metal adhesion. Bonding methods are not limited to the above-described methods.

Complete heat-dissipating part 7 in a heatsink apparatus is described below with reference to FIGS. 5(a), 5(b), 6 (a) and 6 (b). A pair of radiators 1 is disposed in parallel at a predetermined distance. L-shaped connecting tubes 8 are connected to outlet 6 of one of radiators 1 and to inlet 5 of the other radiator 1 respectively.

Connecting tubes 8 are formed of elastic rubber material. Pipe 9 is provided to connect respective connecting tubes 8. Pipe 9 is preferred to be formed of metal, but may be formed of plastics. Further, connecting tubes 8 and pipe 9 may be formed in a U shape of a same rubber material.

Radial fans 10 are provided between the middle of radiators 1 placed in parallel. Rectifying members 11 and 12, which efficiently flow air blown from radial fans 10, are also disposed between the middle of radiators 1 in parallel.

Radial fans 10 employ radial fans that blow the air, which enters from a rotating axial direction of blades of radial fans 10, in a distal direction. Complete heat-dissipating part 7 thus blows the air in two directions. The complete heat-dissipating part may blow the air in one direction instead, employing axial fans that blow the air in a rotating axial direction of blades, from which the air enters.

Further, control methods of radial fans 10 may include constant voltage drive, voltage control drive and PWM drive. Radiators 1, radial fans 10 and rectifying members 11 and 12 are fixed to base 13. On an opposite side of the base, cover 14 is provided having ventilation holes 14a for the radial fans.

Base 13 and cover 14 sandwich radiators 1, radial fans 1 and rectifying members 11 and 12, and form an air duct therebetween. Moreover, base 13 may be provided with ventilation holes to places where radial fans 10 are located to allow air-intake on both sides.

To reduce air resistance from radial fans 10, it is preferable to dispose adjacent flat tubes 2 so that channels 3 are not placed side by side.

Solid line arrows in FIGS. 5(a), 5(b), 6 (a) and 6 (b) show a direction of a coolant flow. Broken line arrows show a direction of an air flow.

Operations of the heatsink apparatus are described below with reference to FIG. 16. Heat-receiving portion 21 is thermally connected to heat-generating portion 23. Heat emitted from heat-generating portion 23 is transferred to the coolant through heat-receiving portion 21. The coolant, to which the heat is transferred from heat-generating portion 23, is sent to inlet 5 by circulation pump 24. Forced through inlet 5 and inlet header 4a, the coolant enters channels 3. While flowing through channels 3, the coolant transfers the heat to flat tubes 2, which then transfer and dissipate the heat to the air generated by radial fans 10.

The coolant, which is cooled to some degree at this point, moves through pipe 9 and then to the other radiator 1 for further cooling in a similar manner.

The cooled coolant passes through reserve tank 22, which has a vapor-liquid separation function, and is sent to heat-receiving portion 21 by circulation pump 24.

Heat-receiving portion 21 and circulation pump 24 may be formed integrally.

### Second Embodiment

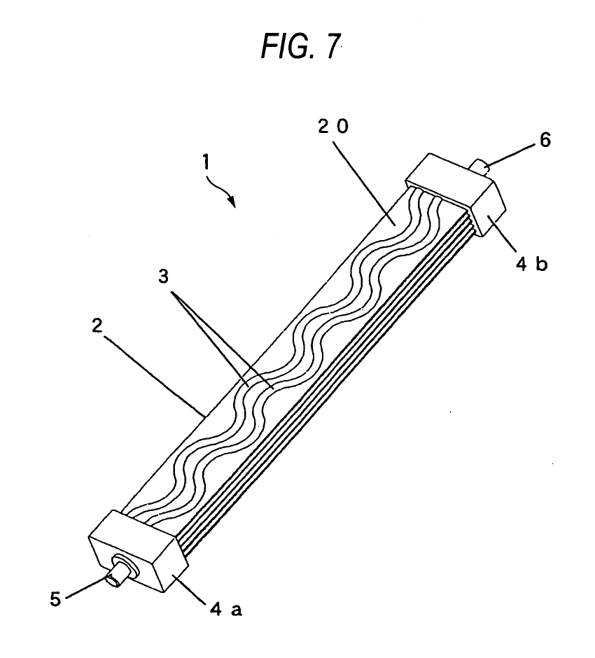

FIG. 7 is a perspective view of a radiator according to a second embodiment of the present invention. Components same as in the first embodiment are provided with same reference numbers and detailed descriptions thereof are omitted.

As shown in FIG. 7, a plurality of flat tubes 2 are stacked in layers having a predetermined distance therebetween. Each of flat tubes 2 is provided with a plurality of channels 3 for coolant circulation and planar portion 20 for heat dissipation. To both ends of flat tubes 2 stacked in layers, hollow inlet header 4a and outlet header 4b are connected. Inlet header 4a is provided with inlet 5 for a coolant to enter and outlet header 4b with outlet 6 for the coolant to discharge.

Inlet 5 and channels 3 are connected via a hollow portion of inlet header 4a. Outlet 6 and channels 3 are connected via a hollow portion of outlet header 4b.

Flat tube 2 is provided with two serpentine channels 3 having a same shape, which double fluid volume of the circulating coolant and thereby further improve heat dissipation performance.

### Third Embodiment

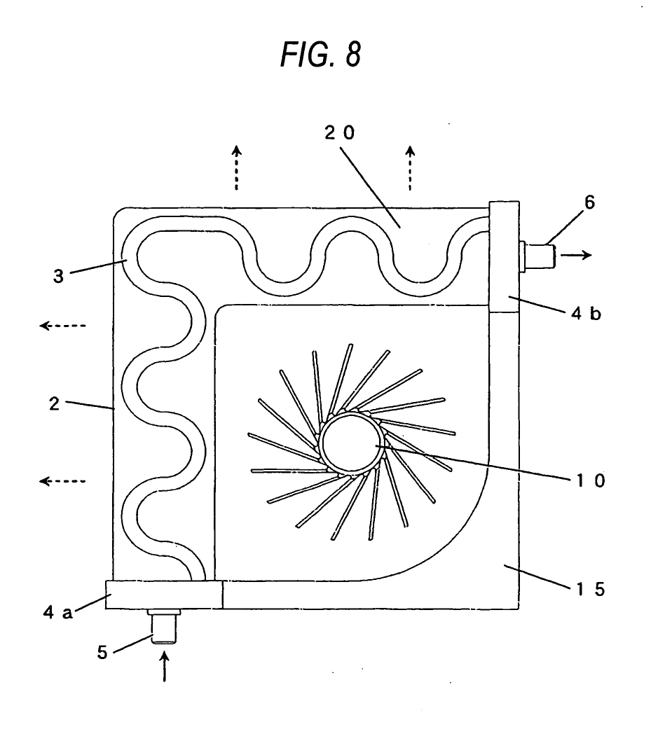

FIG. 8 is a plain view of an uncovered complete heat-dissipating part installed with a radiator according to a third embodiment of the present invention. Components same as in the first embodiment are provided with same reference numbers and detailed descriptions thereof are omitted.

A plurality of flat tubes 2 having an L-shape and being provided with channels 3 and planar portions 20 for heat dissipation are stacked in layers having a predetermined distance therebetween. To both ends of flat tubes 2 stacked in layers, hollow inlet header 4a and outlet header 4b are connected. Inlet header 4a is provided with inlet 5 for a coolant to enter and outlet header 4b with outlet 6 for the coolant to discharge.

Inlet 5 and channels 3 are connected via a hollow portion of inlet header 4a. Outlet 6 and channels 3 are connected via a hollow portion of outlet header 4b.

Inlet header 4a and outlet header 4b are disposed at an angle of 90 degrees.

At an opposite corner to L-shaped flat tubes 2, L-shaped rectifying member 15 is provided. Radial fan 10 is provided between L-shaped rectifying member 15 and L-shaped flat tubes 2. Rotation of radial fan 10 blows air to two directions at an angle of 90 degrees.

Therefore, blowing the air to L-shaped flat tubes 2 using radial fan 10 forcibly and efficiently dissipates heat from flat tubes 2.

### Forth Embodiment

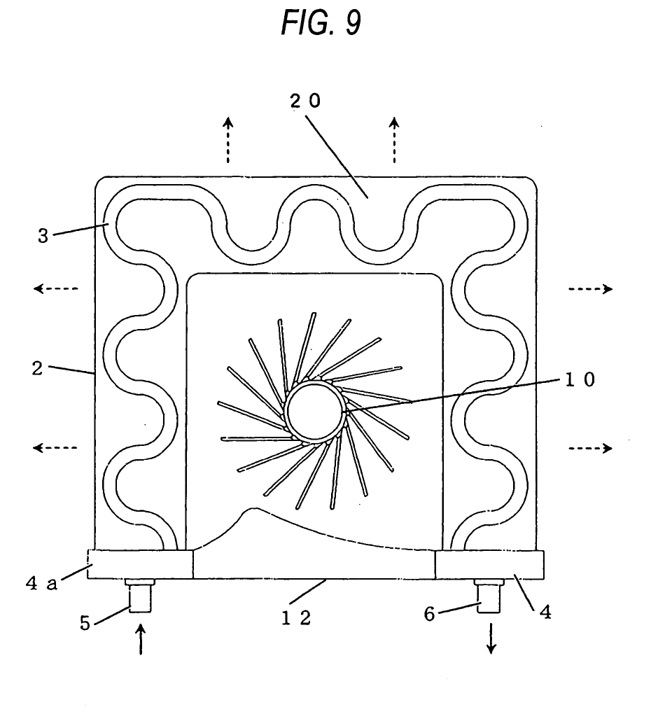

FIG. 9 is a plain view of an uncovered complete heat-dissipating part installed with a radiator according to a forth embodiment of the present invention. Components same as in the first embodiment are provided with same reference numbers and detailed descriptions thereof are omitted.

A plurality of flat tubes 2 having a U shape and being provided with channels 3 and planar portions 20 for heat dissipation are stacked in layers having a predetermined distance therebetween.

To both ends of U-shaped flat tubes 2 stacked in layers, hollow inlet header 4a and outlet header 4b are connected. Inlet header 4a is provided with inlet 5 for a coolant to enter and outlet header 4b with outlet 6 for the coolant to discharge.

Inlet 5 and channels 3 are connected via a hollow portion of inlet header 4a. Outlet 6 and channels 3 are connected via a hollow portion of outlet header 4b. Inlet header 4a and outlet header 4b are disposed in a same direction and rectifying member 12 is provided therebetween. Radial fan 10 is provided at the center of U-shaped flat tubes 2. Rotation of radial fan 10 blows air to three respective directions.

Therefore, U-shaped flat tubes 2 have little air resistance. Blowing the air using radial fan 10 further forcibly and efficiently dissipates heat from flat tubes 2.

### Fifth Embodiment

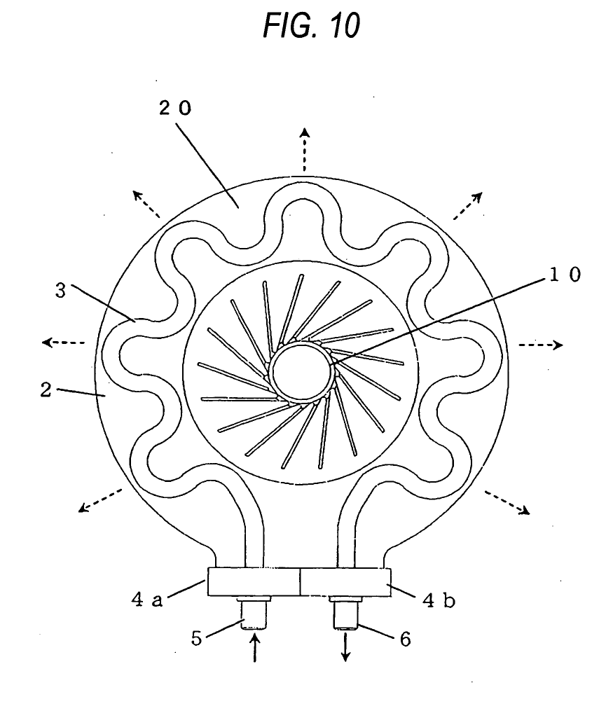

FIG. 10 is a plain view of an uncovered complete heat-dissipating part installed with a radiator according to a fifth embodiment of the present invention. Components same as in the first embodiment are provided with same reference numbers and detailed descriptions thereof are omitted.

Flat tube 2 has an annular shape and is provided with channel 3 and planar portion 20 for heat dissipation. A portion where an inlet and an outlet of channel 3 are located protrudes out of the annular shape.

A plurality of flat tubes 2 are stacked in layers having a predetermined distance therebetween. To both ends of flat tubes 2 stacked in layers, where the inlet and the outlet of channels 3 are located, hollow inlet header 4a and outlet header 4b are connected. Inlet header 4a is provided with inlet 5 for a coolant to enter and outlet header 4b with outlet 6 for the coolant to discharge.

Inlet 5 and channels 3 are connected via a hollow portion of inlet header 4a. Outlet 6 and channels 3 are connected via a hollow portion of outlet header 4b. Inlet header 4a and outlet header 4b are disposed in a same direction. Inlet header 4a and outlet header 4b may be formed integrally, provided that inlet header 4a and outlet header 4b are divided by a partitioning wall.

Radial fan 10 is provided at the center of annular flat tubes 2. Rotation of radial fan 10 blows air to all directions, except for a portion where inlet header 4a and outlet header 4b are located.

Therefore, annular flat tubes 2 have little air resistance. Blowing air using radial fan 10 evenly sends the air in an entire area and thereby forcibly and efficiently dissipates heat from flat tubes 2.

### Sixth Embodiment

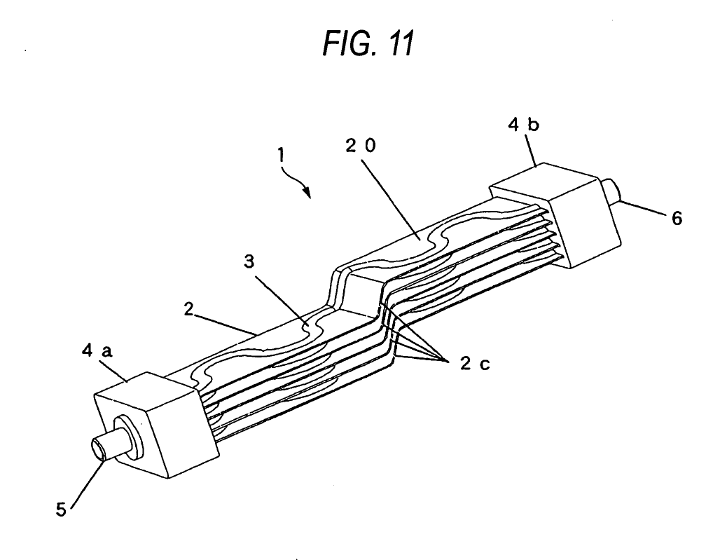

FIG. 11 is a perspective view of a radiator according to a sixth embodiment of the present invention. Components same as in the first embodiment are provided with same reference numbers and detailed descriptions thereof are omitted.

As shown in FIG. 11, a plurality of flat tubes 2 are stacked in layers having a predetermined distance therebetween. Each of flat tubes 2 is provided with a channel 3 for coolant circulation and planar portion 20 for heat dissipation. Flat tubes 2 are folded so as to provide height difference 2c in a layer direction.

To both ends of flat tubes 2 stacked in layers, hollow inlet header 4a and outlet header 4b are connected. Inlet header 4a is provided with inlet 5 for the coolant to enter and outlet header 4b with outlet 6 for the coolant to discharge.

Inlet 5 and channels 3 are connected via a hollow portion of inlet header 4a. Outlet 6 and channels 3 are connected via a hollow portion of outlet header 4b.

Providing height difference 2c allows air cooling in a different height direction when, for example, a radial fan blows air, thereby expanding a heat-dissipating surface area while wasting no heat-dissipating space inside an electronic device.

### Seventh Embodiment

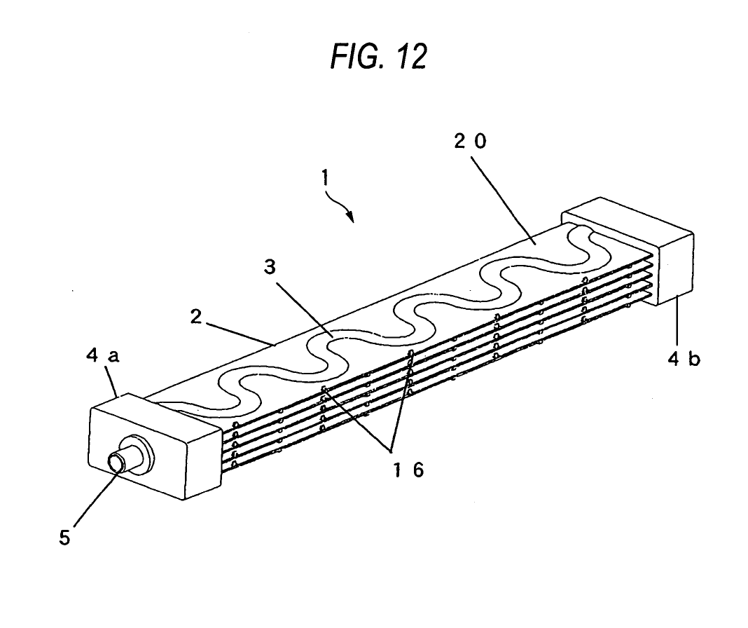

FIG. 12 is a perspective view of a radiator according to a seventh embodiment of the present invention. Components same as in the first embodiment are provided with same reference numbers and detailed descriptions thereof are omitted.

As shown in FIG. 12, a plurality of flat tubes 2 are stacked in layers having a predetermined distance therebetween. Each of flat tubes 2 is provided with a channel 3 for coolant circulation and planar portion 20 for heat dissipation.

Provided on external edges of flat tubes 2 are a plurality of projections 16, which are press-formed when flat plates 2a are processed. To both ends of flat tubes 2 stacked in layers, hollow inlet header 4a and outlet header 4b are connected. Inlet header 4a is provided with inlet 5 for the coolant to enter and outlet header 4b with outlet 6 for the coolant to discharge. Inlet 5 and channels 3 are connected via a hollow portion of inlet header 4a. Outlet 6 and channels 3 are connected via a hollow portion of outlet header 4b.

Therefore, providing the plurality of projections 16 on external surfaces of flat tubes 2 does not only increase a heat-dissipating surface area, but also causes turbulence at the plurality of projections 16 when a radial fan blows air to gaps between the flat tubes stacked in layers, thereby further improving heat dissipation effects of flat tubes 2.

### Eighth Embodiment

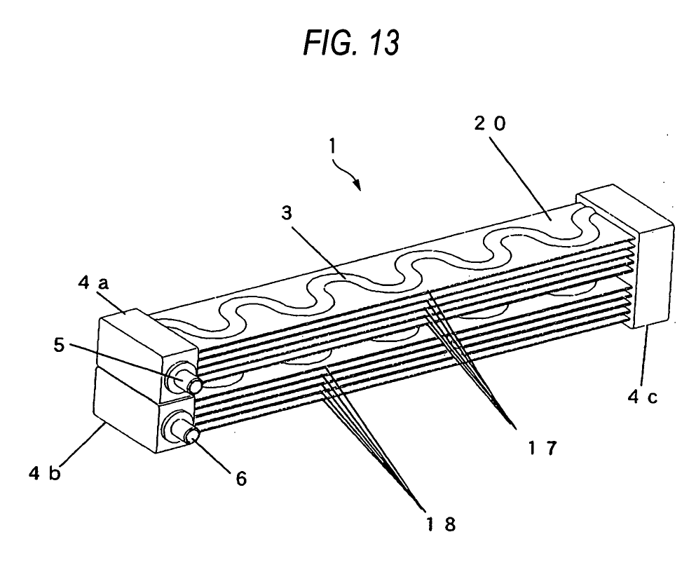

FIG. 13 is a perspective view of a radiator according to an eighth embodiment of the present invention. Components same as in the first embodiment are provided with same reference numbers and detailed descriptions thereof are omitted.

As shown in FIG. 13, a plurality of flat tubes 2 are stacked in layers having a predetermined distance therebetween. Each of flat tubes 2 is provided with channel 3 for coolant circulation and planar portion 20 for heat dissipation. At an end of flat tubes 2 stacked in layers, hollow inlet header 4a is connected to an upper half of the end and hollow outlet header 4b to a remaining lower half of the end.

To the other end of flat tubes 2, hollow intermediate header 4c is connected. Inlet header 4a is provided with inlet 5 for the coolant to enter and outlet header 4b with outlet 6 for the coolant to discharge.

The radiator includes: inlet header 4a having a hollow shape and being provided with inlet 5 for the coolant to enter; a first group of flat tubes 17 connecting to inlet header 4a on one end; intermediate header 4c having a hollow shape and connecting to another end of the first group of flat tubes 17; a second group of flat tubes 18 connecting to intermediate header 4c on one end; and outlet header 4b having a hollow shape, being provided with outlet 6 for the coolant to discharge and connecting to another end of the second group of flat tubes 18. The first group of flat tubes 17 and the second group of flat tubes 18 form channels for the coolant and connect inlet header 4a and outlet header 4b having intermediate header 4c therebetween, and thus ensure a heat-dissipating surface area on the second group of flat tubes 18, in addition to a heat-dissipating surface area on the first group of flat tubes 17, thereby providing high heat dissipation performance and simplifying a structure of the radiator.

Inlet header 4a and outlet header 4b may be formed integrally, provided that inlet header 4a and outlet header 4b are divided by a partitioning wall. Inlet 5 and channels 3 are connected via a hollow portion of inlet header 4a. Outlet 6 and channels 3 are connected via a hollow portion of outlet header 4b.

Further, a hollow portion of intermediate header 4c connects channels 3 of flat tubes 2 connected to inlet header 4a and channels 3 of flat tubes 2 connected to outlet header 4b.

The coolant sent by a circulation pump (not shown in the figure) enters from inlet 5, passes through a hollow portion of inlet header 4a, then enters channels 3 of respective flat tubes 2 connected to inlet header 4a.

The coolant forced through channels 3 then discharges to a hollow portion of intermediate header 4c and enters channels 3 of respective flat tubes 2 connected to outlet header 4b.

The coolant forced through channels 3 passes through a hollow portion of outlet header 4b and discharges from outlet 6. An arrow in FIG. 13 shows a direction of a coolant flow.

### Ninth Embodiment

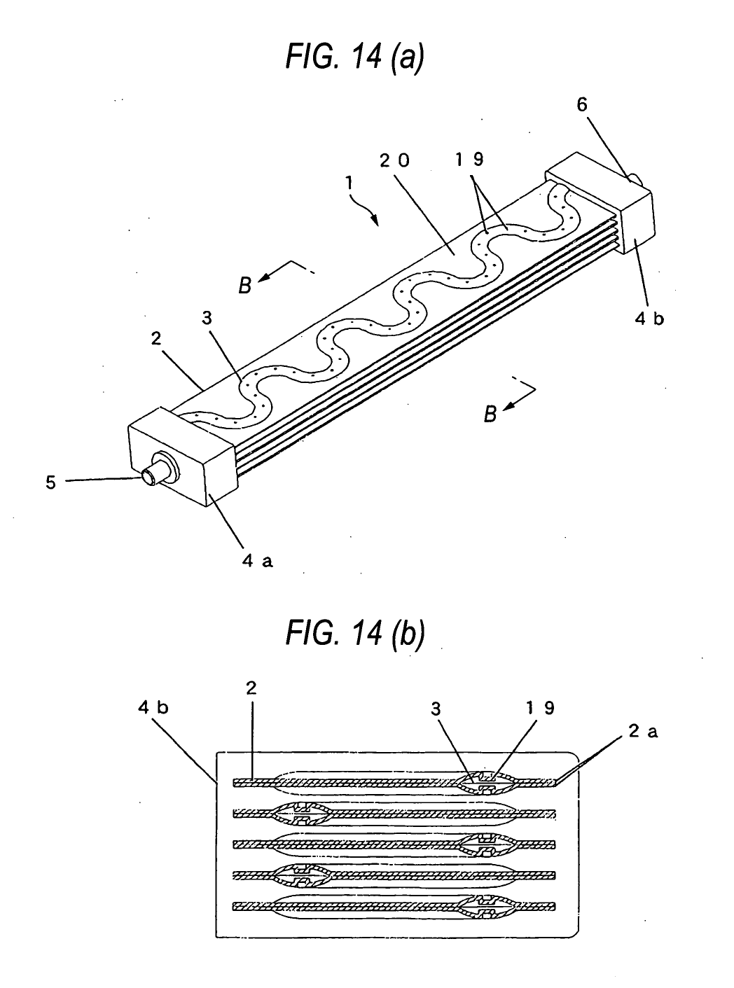

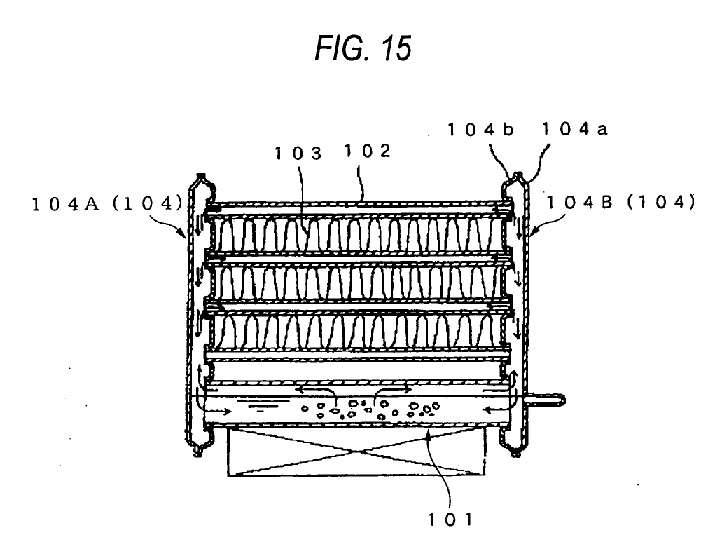

FIG. 14 (a) is a plain view of a radiator according to a ninth embodiment of the present invention. FIG. 14 (b) is a cross-sectional view along line BB of FIG. 14 (a). Components same as in the first embodiment are provided with same reference numbers and detailed descriptions thereof are omitted.

A plurality of flat tubes 2 are stacked in layers having a predetermined distance therebetween. Each of flat tubes 2 is provided with a channel 3 for coolant circulation and planer portion 20 for heat dissipation.

Provided on an internal surface of channels 3 are a plurality of convex portions 19, which are press-formed when flat plates 2a are processed. To both ends of flat tubes 2 stacked in layers, hollow inlet header 4a and outlet header 4b are connected. Inlet header 4a is provided with inlet 5 for the coolant to enter and outlet header 4b with outlet 6 for the coolant to discharge.

Further, inlet 5 and channels 3 are connected via a hollow portion of inlet header 4a. Outlet 6 and channels 3 are connected via a hollow portion of outlet header 4b.

Therefore, providing the plurality of convex portions 19 increases a surface area for heat transfer from the coolant to flat tubes 2. At the same time, the coolant tends to be turbulent as passing through, which further improves heat transfer efficiency from the coolant to flat tubes 2.

It is noted that the foregoing examples have been provided merely for the purpose of explanation and are in no way to be construed as limiting of the present invention. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

This application is based on the Japanese Patent Application No. 2005-109673 filed on Apr. 6, 2005, entire content of which is expressly incorporated by reference herein.

What is claimed is:

1. A radiator comprising:
a first header having a hollow shape and being provided with an inlet for a coolant;
flat tubes having channels for the coolant and being connected to the first header; and
a second header having a hollow shape, being provided with an outlet for the coolant and being connected to another end of the flat tubes, wherein:
the flat tubes have planar portions along the channels; and
the flat tubes are provided between the first header and the second header and are stacked in layers.

2. A radiator circulating a coolant therein and dissipating heat of the coolant, the radiator comprising:
an inlet header having a hollow shape and being provided with an inlet for the coolant to enter;
a first group of flat tubes connecting to the inlet header on one end;
an intermediate header having a hollow shape and connecting to another end of the first group of flat tubes;
a second group of flat tubes connecting to the intermediate header on one end; and
an outlet header having a hollow shape, being provided with an outlet for the coolant to discharge and connecting to another end of the second group of flat tubes; wherein
the first group and the second group of flat tubes form channels for the coolant and connect the inlet header and the outlet header having the intermediate header therebetween.

3. The radiator according to one of claims 1 and 2, wherein two sheets of a same flat plate having a channel on one side are bonded to form the flat tube.

4. The radiator according to one of claims 1 and 2, wherein a flat plate having a channel on one side and a flat plate having no channel are bonded to form the flat tube.

5. The radiator according to one of claims 3 and 4, wherein the channel provided on the flat plate is press-formed.

6. The radiator according to one of claims 1 and 2, wherein the channels provided in the flat tubes have a serpentine shape.

7. The radiator according to one of claims 1 and 2, wherein the channels provided in the flat tubes have on an internal surface thereof at least one projection.

8. The radiator according to one of claims 1 and 2, wherein the flat tubes have on an external surface thereof at least one projection.

9. The radiator according to one of claims 1 and 2, wherein the flat tubes have at least one height difference.

10. The radiator according to one of claims 1 and 2, wherein the coolant is an antifreeze solution.

11. A heatsink apparatus having the radiator according to one of claims 1 to 10.

12. A heatsink apparatus having the radiator according to one of claims 1 to 10, which has L-shaped flat tubes, and a radial fan.

13. A heatsink apparatus having the radiator according to one of claims 1 to 10, which has U-shaped flat tubes, and a radial fan.

14. A heatsink apparatus having the radiator according to one of claims 1 to 10, which has annular flat tubes, and a radial fan.
